(19) United States
(12) Patent Application Publication
(10) Pub. No.: US 2011/0189325 A1
(43) Pub. Date: Aug. 4, 2011

(54) Process and technical arrangement to produce in series single crystal penetrator rods of an alloy of 40wt% tungsten-40wt% titanium-20wt% osmium to replace depleted uranium which causes after use hazardous environmental problems

(76) Inventor: Juergen Wisotzki, Darmstadt (DE)

(21) Appl. No.: 12/801,433

(22) Filed: Jun. 9, 2010

(30) Foreign Application Priority Data
Feb. 2, 2010 (EP) 10001018.0

(51) Int. Cl. B22F 3/00; C22C 30/00; C30B 15/00

(52) U.S. Cl. 425/78; 420/580; 117/13

(57) ABSTRACT

A new process and technical arrangement to produce in series penetrator rods which have a true single crystal structure consisting of an alloy of 40% by weight Tungsten, 40% by weight Titanium, 20% by weight Osmium. Those single crystal penetrator rods do not break up upon impact on a target, the material sleeves back over the surface whilst the core drives forward and penetrates till the given velocity is used up. This phenomena is only achievable with a single crystal structure and leads to a size and weight reduction because there is not any material lost upon impact on the target as it happens with all penetrator rods which have a grain structure and as they are used today. This alloy as named above has the highest density and highest hardness possible, caused by the crystal growth process and it permits the user to stay out of reach of any opponent not using the same material.

The present invention is a new process and technical arrangement to produce in series single crystal penetrator rods of an alloy of 40 wt % Tungsten-40 wt % Titanium-20 wt % Osmium to replace depleted Uranium which causes after use hazardous environmental problems. With this new alloy the highest penetration capability can be reached, weight reduced and the firing distance enlarged.

### STATE OF THE ART

Penetrator rods as they are used today in military and other applications are high mass material alloys, such as tungsten carbide and they have a grain structure. In some cases depleted uranium is used, which causes a hazardous environmental problem, because if it burns on air, the material is turned into uranium-oxide, a powder which is light and distributes itself with the wind, causing leukemia and other deadly illness. The grain structure of the presently used materials such as tungsten carbide breaks up on impact at the target, caused by the high velocity and the impurities with lighter elements residing in the grain boundaries. Each grain of such grain structures are single crystals with different crystal orientations and behave differently to deformation forces. Out of those reasons, a large portion of the penetrator rod falls unused to the ground and this fact requires an oversize and high quantity of material. This becomes a weight issue and the distance to be bridged towards an opponent in military applications requires a high energy at the firing point. Due to the high mass of the used materials, the limitations are obvious.

### BRIEF DESCRIPTION OF THE DRAWINGS

FIG. 1 is a schematic view of the circular rod form of the preferred embodiment of the invention.

FIG. 2 is a microphotagraph of the surface of the material used in the preferred embodiment of the invention.

FIG. 3 is a schematic view of the compression of powder in a high vacuum dye in the preferred embodiment of the invention.

FIG. 4 is a schematic view of the float zoning process in the preferred embodiment of the invention.

### DETAILED DESCRIPTION OF THE INVENTION

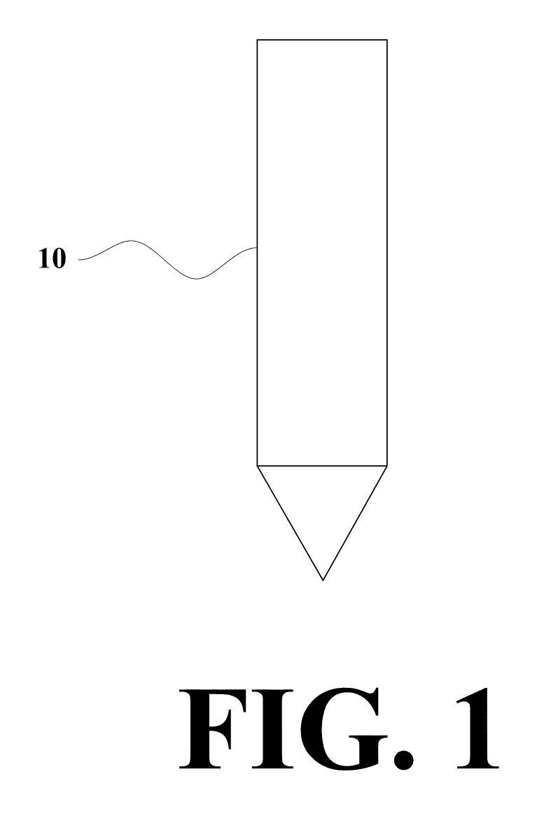

In practical experiments it was found, that true single crystal structures of the alloy of 40 wt % Tungsten-40 wt % Titanium-20 wt % Osmium could be achieved, leading to a circular rod form, which can be used as penetrator if given a high velocity, as shown in FIG. 1. FIG. 1 shows a grain free single crystal rod 10, preferably with a diameter up to 30 millimeters, with an overall diameter variation of 0.2 millimeters. Cage mounting is required during the production process. The alloy of the present invention can replace depleted Uranium in all applications. Rod 10 is a single crystal penetrator bolt, consisting by weight 40% tungsten, 40% titanium and 20% osmium. Due to its high density and ductile single crystal structure, there is no break up on impact.

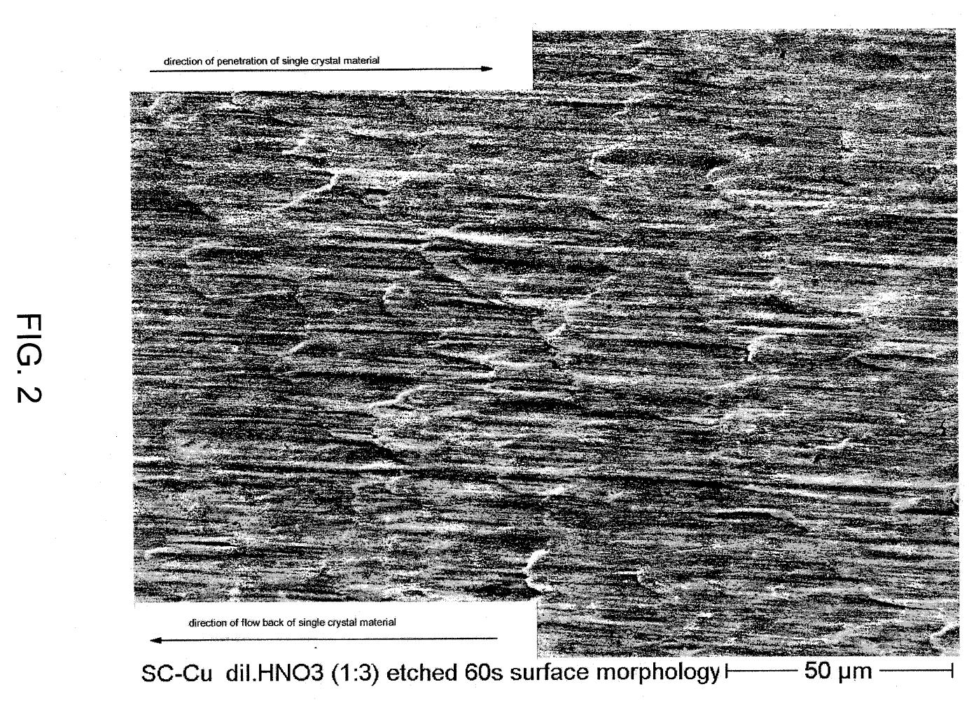

As it can be seen on FIG. 2, upon deformation, the material sleeves back over the surface of the rod opposite to the penetration direction of the rod. Due to the fact that through this phenomena, there is no loss of material like it happens with a grain structure, penetrator rods for military and other applications can be made smaller in size, creating identical or higher penetration length in another material. This is an important strategic factor, because what is smaller needs less energy and can fly further if using the same amount of energy at the starting point. In the military application of such ammunition, this leads to a higher firing distance and opponents can not defend themselves, if they use penetrator rods with a grain structure. This is a severe strategic advantage to the user of the invention.

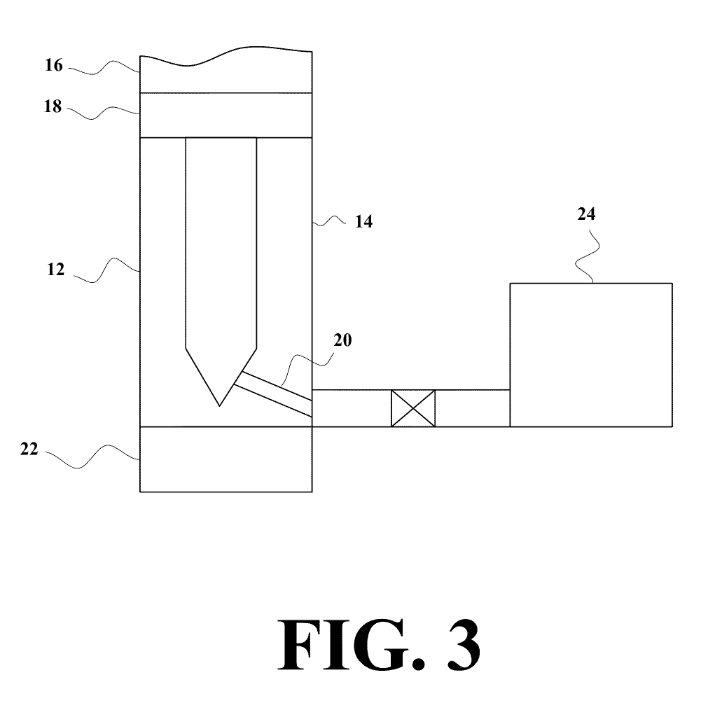

FIG. 3 shows the serial production of single crystal high mass material penetrator rods, consisting of an alloy of tungsten, titanium and osmium. The production process of such penetrator rods requires the following proceedings. In the first step, powder is compressed in a high vacuum dye. The powder of Tungsten, Titanium and Osmium is mixed in a rotating mixing drum in the ratio of 40 wt % Tungsten-40 wt % Titanium-20 wt % Osmium. A stainless steel dye 12 as shown in FIG. 3 will be filled with the mixed powder 14 and the powder will be compressed with a piston 16 of a high tonnage press and dye piston 18, whilst at the same time the air is taken out of the chamber of the dye to reduce the oxygen content of the air between the granules of the compressed powder. FIG. 3 also shows the dye filter 20, the table of the press 22, and the root stack vacuum system 24.

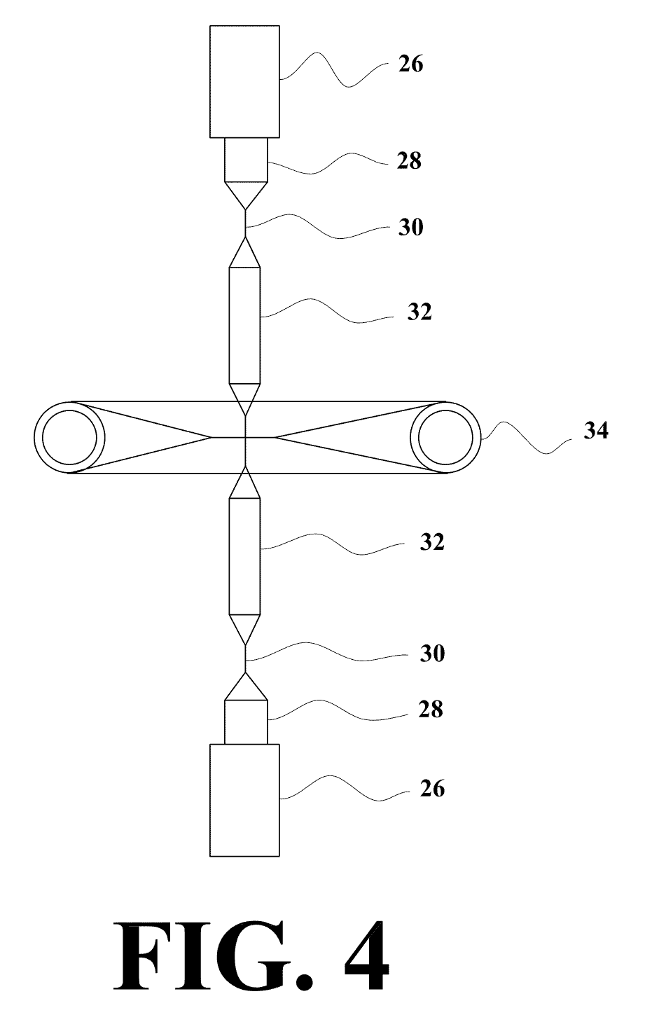

FIG. 4 shows the second step of the serial production of single crystal high mass material penetrator rods, consisting of an alloy of tungsten, titanium and osmium, which is a float zoning process and arrangement inside a chamber. Shown are lowering rods 26 that drive up and down and rotate left and right, high mass material powder rods 28, necking 30, single crystals 32, and an rf-coil with concentrator 34. The compressed rod is inserted in a stainless steel chamber of the production apparatus and driven up and down in the concentrator of the rf-coil through which the energy for the heating up of the material is transferred. Both lowering and rotating rods at the top and the bottom of the rod rotate in the same direction during this phase of the process. The gradual heating up begins with low vacuum and continues under a hydrogen enriched atmosphere of an inert gas reducing arcing caused by the oxygen, which causes electrical failures of the rf-generator. Upon reaching the melting point, the lower clamping rod is stopped and gradually rotates in the opposite direction as the upper clamping rod does, whilst the concentrator of the rf-coil is positioned at the bottom end of the now fairly solid rod. The upper rod is pulled upwards under rotation and a thin segment is created between the two rod pieces, which leads to separation of grains till a single grain is developed as shown in FIG. 4. This part of the process is called “necking” and commonly used in the Czochralski crystal growth process if no seed crystal is available. From the first “leading” sector at the bottom of the arrangement the growth continues upwards by driving both clamping rods downwards till the required length of the first penetrator rod is reached and thinned down to the next “necking” sector from where the growth process of the next penetrator rod is continued. The length of each rod is selective and diameter control regulates the diameter to an accuracy of +/−0.2 mm. During the growth process of the rod grooves can be formed into the rod to hold the cage for the final use of the rod. In the designed equipment -in one continuous run- up to 10 rods with a diameter of 30 mm and a length of 200 mm can be produced. The use of Titanium as an alloy serves the purpose to harden the alloy but at the same time it is used as an ignition source to reduce the energy consumption to reach the melting point of the alloy faster. The same principle can be used to grow high purity single crystal rods of any high mass material, such as Tungsten, Tantalum, Molybdenum and alloy combinations of them.

1. A single crystal rod, comprising:
a single crystal rod made of an alloy of 40% by weight tungsten, 40% by weight titanium, and 20% by weight osmium, grown to the final usable shape in a support free float zoning process.

2. A support free float zoning process with an internal arrangement and control to produce single crystal rods, comprising the steps of:
producing single crystal rods in a serial process;
necking the intervals between each grown rod, down to a diameter 1.0 millimeters; and
separating the grown crystal rods from each other.

3. A method of producing compressed rods, comprising the steps of:
providing a powder of high purity tungsten, titanium and osmium
compressing the powder with a dye to reduce the oxygen content between the granules of the powder.
